(19) United States
(12) Patent Application Publication
(10) Pub. No.: US 2006/0216873 A1
(43) Pub. Date: Sep. 28, 2006

(54) Image display device and the manufacturing method therefor

(76) Inventors: Masakazu Sagawa, Inagi (JP); Toshiaki Kusunoki, Tokorozawa (JP); Tomoki Nakamura, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/325,551

(22) Filed: Jan. 5, 2006

(30) Foreign Application Priority Data
Mar. 25, 2005 (JP) 2005-088591

(51) Int. Cl. H01L 21/84; H01L 21/00

(52) U.S. Cl. 438/149; 438/125

(57) ABSTRACT

The present invention provides an image display device, by which it is possible to prevent oxidation of a terminal in anodic oxidation processing of a bottom electrode (data line) to make up a thin-film type electron source, to improve production yield and high reliability, and to increase the thickness of an interlayer insulator formed at the same time.

A resist pattern 18 to form a terminal 40A of data line is limited to the bus line of the terminal 40A. Width of the resist pattern 18 is set to a value approximately equal to a value of the width of the bus line of the terminal 40A so that the resist pattern may not be present on the glass substrate, which is positioned between bus lines. The resist pattern is discontinuously formed by providing a slit 18A in extending direction of the bus line of the terminal 40A. The size of the resist pattern 18 is set to a value to match the width of the electron source based on the above results.

### BACKGROUND OF THE INVENTION

The present invention relates to an image display device and a method for manufacturing the same. In particular, the invention relates to an image display device, which is also called an emissive type flat panel display using a thin-film type electron source array.

A type of image display device has been developed, which uses emission type electron sources, also called thin-type electron sources, in micro-size and of integratable type. Some of the thin-film type electron sources are designed in 3-layer thin-film structure comprising a top electrode, an electron accelerator, and a bottom electrode. Voltage is applied between the top electrode and the bottom electrode, and electrons are emitted into vacuum space from the surface of the top electrode. For instance, various types of devices are known: MIM (metal-insulator-metal) type where a metal layer, an insulator and a metal layer are laminated on each other, MIS (metal-insulator-semiconductor) type where a metal layer, an insulator, and a semiconductor layer are laminated on each other, metal-insulator-semiconductor-metal type, EL type, porous silicon type, etc.

The Patented References 1 and 2 describe an MIM type cathode substrate. The Non-Patented Reference 1 describes a metal-insulator-semiconductor type. The Non-Patented Reference 2 describes a metal-insulator-semiconductor-metal type. The Non-Patented Reference 3 describes an EL type, and the Non-Patented Reference 4 discloses a porous silicon type.

FIG. 28 is a cross-sectional view to explain basic structure of a thin-film type electron source by taking an example of the MIM type. FIG. 29 is a drawing to explain operating principle of the thin-film type electron source. The MIM type thin-film electron source comprises a bottom electrode 13 formed on a substrate 10, a top electrode 13 laminated to cross the bottom electrode via a tunneling insulator (also called electron accelerator) 12, and an interlayer insulator 14. Electric current is supplied to the top electrode 13 via a top electrode bus line 16 and a contact electrode 15.

Now, description will be given on operating principle of the thin-film type electron source shown in FIG. 28 by referring to FIG. 29. In FIG. 29, driving voltage Vd is applied between the top electrode 13 and the bottom electrode 11, and electric field within the tunneling insulator 12, serving as an electron accelerator, is turned to about 1 to 10 MV/cm. Then, electrons near Fermi level in the bottom electrode 11 pass through potential barrier due to tunneling phenomena. Electrons are injected to a conduction band of the tunneling insulator 12 and the top electrode 13, and the electrons are turned to hot electrons.

These hot electrons are diffused in the tunneling insulator 12 and in the top electrode 13 and lose energy. A part of the hot electrons having energy higher than the work function φ of the top electrode 13 are emitted into vacuum space 20. In other types of thin-film electron sources, the principle may be somewhat different but there are common features that hot electrons are emitted via the thin top electrode 13.

The bottom electrode comprising the thin-film type electron sources, the top electrode arranged to intersect the bottom electrode, and a top electrode bus line for supplying electric current to the top electrode are placed in form of a 2-dimensional matrix to make up a thin-film type electron source array. Then, a display signal is applied to the bottom electrode, and a scan signal is applied to the top electrode (to electrode bus line), and electrons from the thin-type electron source on the intersections are directed toward phosphor and are excited. As a result, an image display device is made up. In this case, the top electrode but line is turned to scan line bus line. The thin-film type electron sources are described, for example, in the Patented References 1 and 2 and the Non-Patented Reference 1, 2, 3 and 4.
[Patented Reference 1] JP-A-7-65710
[Patented Reference 2] JP-A-10-153979
[Patented Reference 3] JP-A-8-179361
[Non-Patented Reference 1] J. Vac. Sci. Technol.; B11(2), pp. 429-432 (1993).
[Non-Patented Reference 2] Jpn. J. Appl. Phys.; Vol. 36, p. 939.
[Non-Patented Reference 3] Jpn. J. Appl. Phys.; Vol. 63, No. 6, p. 592.
[Non-Patented Reference 4] Jpn. J. Appl. Phys.; Vol. 66, No. 5, p. 437.

As described above, in this type of image display device, a display signal is applied on the bottom electrode, and a scan signal is applied on the top electrode (top electrode bus line), and thin-film type electron sources at intersections are selected. For this reason, insulation between the bottom electrode of the thin-film type electron source array and the top electrode (top electrode bus line) is very important. If insulation between the two electrodes is poor, electric short-circuiting may occur between the bottom electrode and the top electrode or the top electrode bus line, and this may cause defects in the image. In this respect, the tunneling insulator, serving as an electron accelerator, and the interlayer insulator for limiting the electron emission region must be free of defects. The bottom electrode is made of aluminum or aluminum alloy. The tunneling insulator and the interlayer insulator are formed by anodic oxidation of aluminum or aluminum alloy. In this case, the terminal of the bottom electrode is connected with external circuit. For this reason, total region is designed as a non-oxidized region.

Electrochemical film deposition method called anodic oxidation as used for the formation of the tunneling insulator and the interlayer insulator is extremely superior to the other film deposition method in providing uniform and even film quality and film thickness, and it is suitable for the formation of a display panel, which makes up a large scale (large area) image display device comprising this type of electron source array.

In the anodic oxidation, if there is a point where electric current does not flow due to foreign object attached on the surface, poor insulation occurs. Also, when the display panel is made up by the thin-film type electron source array, atmospheric pressure applied on the cathode substrate via spacers may induce mechanical damage on the interlayer insulator of the thin-film type electron source array, and this may lead to dielectric breakdown of time zero. Further, capacitance of the thin-film type electron source is generally higher than that of liquid crystal element. This is because specific dielectric constant of alumina, serving as insulator, is as high as 10, and also because film thickness is as thin as about 10 nm. For this reason, a driving circuit chip having sufficiently high electric current supplying ability (IC or LSI) must be used, and this may cause higher cost for the circuit compared with liquid crystal element.

In the capacitance, the tunneling insulator and the interlayer insulator occupy one half of the capacitance respectively. The tunneling insulator is about 1/10 in film thickness and area compared with the interlayer insulator. On the other hand, dielectric constant is the same for these two (specific dielectric constant: up to 10), and capacitance is almost the same. To decrease the parasitic capacitance, film thickness of the interlayer insulator should be increased, while it is difficult to simply increase the oxidation voltage because of the relation with withstand voltage of the resist mask for local oxidation.

For the purpose of turning the terminal to non-oxidized region, the resist for preventing the oxidization (hereinafter also called “resist mask”) is formed on the terminal. However, the resist mask may be cracked during anodic oxidation processing or peeling may occur locally, and the effective functioning of the terminal may not be assured. Such phenomena become more remarkable when anodic oxidation voltage is increased, and this is one of the causes to decrease production yield and to hinder the thickening of the film of the interlayer insulator formed at the same time. This results in the decrease of production yield and lower reliability of the image display device.

To avoid poor contact due to surface protrusion caused when gate insulator is formed by anodic oxidation on the gate terminal made of aluminum or aluminum alloy on the active matrix panel of the liquid crystal display device, the Patented Reference 3 discloses an arrangement to provide a plurality of non-oxidized regions inside the surface of the terminal of the gate line. However, this is not very effective to prevent cracking of the resist mask in the anodic oxidation processing or to prevent undesirable oxidation due to local peeling.

It is an object of the present invention to provide an image display device, by which it is possible to prevent oxidation of a terminal in anodic oxidation processing of a bottom electrode (data line) to make up a thin-film type electron source, to improve production yield and high reliability, and to increase the thickness of an interlayer insulator formed at the same time.

The image display device according to the present invention is provided with a vacuum panel container, which comprises a cathode substrate where a plurality of thin-film type electron sources are arranged with predetermined spacing, an anode substrate where spot-like or linear phosphor films are arranged to face to each other, a plurality of spacers for supporting said cathode substrate and said anode substrate with predetermined spacing, and a frame glass for maintaining vacuum condition, wherein there are provided a plurality of electric bus lines extending in row direction and in column direction crossing perpendicularly via interlayer insulators, and said thin-film type electron sources are connected with said electric bus lines in column direction and in row direction at positions corresponding to each of intersection coordinates, and image display is performed by line-sequential driving of the cold cathode type electron sources.

The thin-film type electron sources are provided with a bottom electrode, a top electrode and an electron accelerator interposed between these two. The terminal of the bottom electrode is formed by extending the bottom electrode to around the cathode substrate, and a plurality of non-oxidized regions are formed on the terminal. When the interlayer insulator is formed, the non-oxidized region covers almost the entire region over the width of the terminal of the bottom electrode, and this is accomplished by providing discontinuous resist pattern in a direction of the extension of the terminal.

The resist pattern is formed on the pixel region except a portion where the interlayer insulator is provided. By immersing the cathode substrate into a chamber with anodic oxidizing solution, the whole region of the interlayer insulator and the terminal except the non-oxidized portion can be processed by anodic oxidation.

By designing the resist pattern on the terminal as discontinuous, it is possible to increase processing voltage. As a result, the interlayer insulator with sufficiently thick film can be provided. This contributes to the improvement of production yield and to high reliability, and it is useful for the production of the image display device with the interlayer insulator with thick film.

### BRIEF DESCRIPTION OF THE DRAWINGS

FIG. 1 is a plan view to explain an example of arrangement of a cathode substrate to constitute an image display device of the present invention;

FIG. 2 is an enlarged view of an essential portion of an anodic oxidized current feeding terminal shown in FIG. 1;

FIG. 3 represents drawings to explain the problems when processing voltage is increased from 100 V to 200 V to perform anodic oxidation processing for a data line and a common bus line connected to the data line;

FIG. 4 represents drawings to explain first means for suppressing peeling of a resist pattern when the processing voltage is increased;

FIG. 5 represents drawings to show the condition of anodic oxidation processing when a cathode substrate with the resist pattern formed on it shown in FIG. 4 is immersed in an anodic oxidation chamber;

FIG. 6 is an enlarged view of a portion A in FIG. 1 to explain Embodiment 1 of the present invention;

FIG. 7 represents an enlarged view of a portion B shown in FIG. 1;

FIG. 8 represents an enlarged view of a portion C shown in FIG. 1;

FIG. 9 is an enlarged view of a bus line contracting portion of the data line shown in the upper portion of FIG. 8;

FIG. 10 is an enlarged view of a terminal of the data line shown in the upper portion of FIG. 9;

FIG. 11 represents drawings to explain as to whether there is peeling of resist or not in the resist depending on the size of the resist pattern formed on the terminal of the data line;

FIG. 12 represents diagrams to explain withstand voltage on an interlayer insulator due to the value of oxidation voltage to the cathode substrate, which has the data line processed by using the resist pattern as explained in Embodiment 1 of the present invention shown in FIG. 10;

FIG. 13 is a table to explain capacity reducing effect of a pixel having data line, which is processed by using the resist pattern as explained in Embodiment 1 of the present invention shown in FIG. 10;

FIG. 14 represents drawings to explain a method for manufacturing a thin-film type electron source in Embodiment 1 of the present invention;

FIG. 15 represents drawings similar to those of FIG. 14 to explain a method for manufacturing a thin-film type electron source in Embodiment 1 of the present invention;

FIG. 16 represents drawings similar to those of FIG. 14 to explain a method for manufacturing a thin-film type electron source in Embodiment 1 of the present invention;

FIG. 17 represents drawings similar to those of FIG. 15 and FIG. 16 to explain a method for manufacturing a thin-film type electron source in Embodiment 1 of the present invention;

FIG. 18 represents drawings similar to those of FIG. 17 to explain a method for manufacturing a thin-film type electron source in Embodiment 1 of the present invention;

FIG. 19 represents drawings similar to those of FIG. 18 to explain a method for manufacturing a thin-film type electron source in Embodiment 1 of the present invention;

FIG. 20 represents drawings similar to those of FIG. 19 to explain a method for manufacturing a thin-film type electron source in Embodiment 1 of the present invention;

FIG. 21 represents drawings similar to those of FIG. 20 to explain a method for manufacturing a thin-film type electron source in Embodiment 1 of the present invention;

FIG. 22 represents drawings similar to those of FIG. 21 to explain a method for manufacturing a thin-film type electron source in Embodiment 1 of the present invention;

FIG. 23 represents drawings similar to those of FIG. 22 to explain a method for manufacturing a thin-film type electron source in Embodiment 1 of the present invention;

FIG. 24 represents drawings to explain an example of arrangement of an image display device using MIM type cathode substrate;

FIG. 25 represents drawings to explain an example of arrangement of an image display device using MIM type cathode substrate;

FIG. 26 represents cross-sectional views of the image display device, which comprises a cathode substrate and an anode substrate affixed together;

FIG. 27 is an explosive perspective view to explain general features of an example of an overall arrangement of the image display device according to the present invention;

FIG. 28 is a drawing to show a structure of elements of the thin-film type electron source; and

FIG. 29 is a drawing to show operating principle of the thin-film type electron source.

### DETAILED DESCRIPTION OF THE PREFERRED EMBODIMENTS

Detailed description will be given below on embodiments of the present invention referring to the drawings. In the embodiments given below, description will be given, as an example, on a field emission type image display device using MIM type thin-film electron source of hot electron emission type. However, it is needless to say that the present invention is not limited to the image display device using MIM type electron source, and the invention can be applied in the same manner to various types of image display devices using different types of electron sources as already explained in the Background of the Invention.

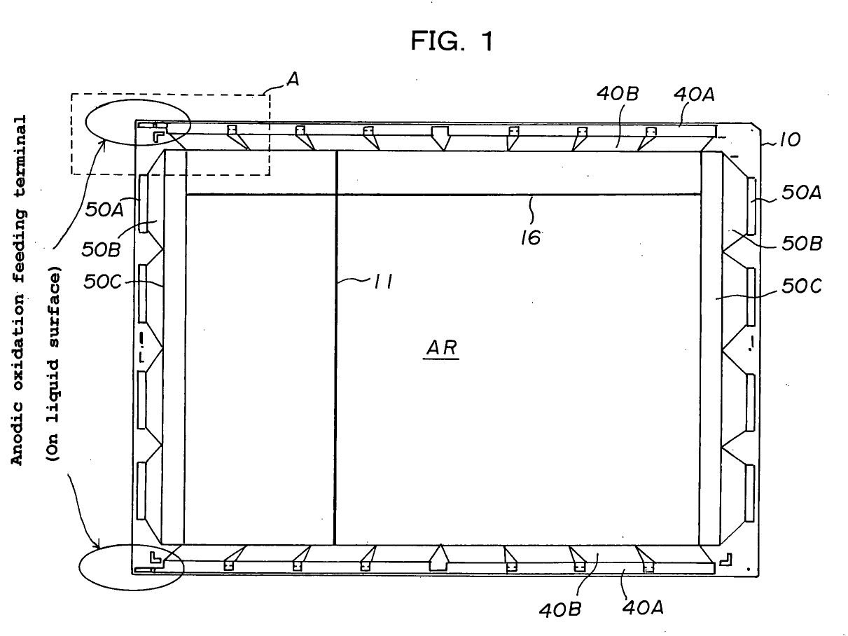

FIG. 1 is a plan view to explain an example of arrangement of a cathode substrate, which makes up the image display device. This image display device is an FED type image display device. On each of longer sides around a display region AR of a cathode substrate 10, a data line terminal 40A provided with a data line driving circuit is arranged (Symbol 40B represents a contracting portion of the terminal). Similarly, on each of shorter sides around the display region AR, a scan line terminal 50A provided with a scan line driving circuit is arranged (Symbol 50B represents a contracting portion of the terminal, and 50C denotes an end portion of the scan line). At an intersection of a data line 11 and a scan line 16, an electron source comprising a pixel is formed.

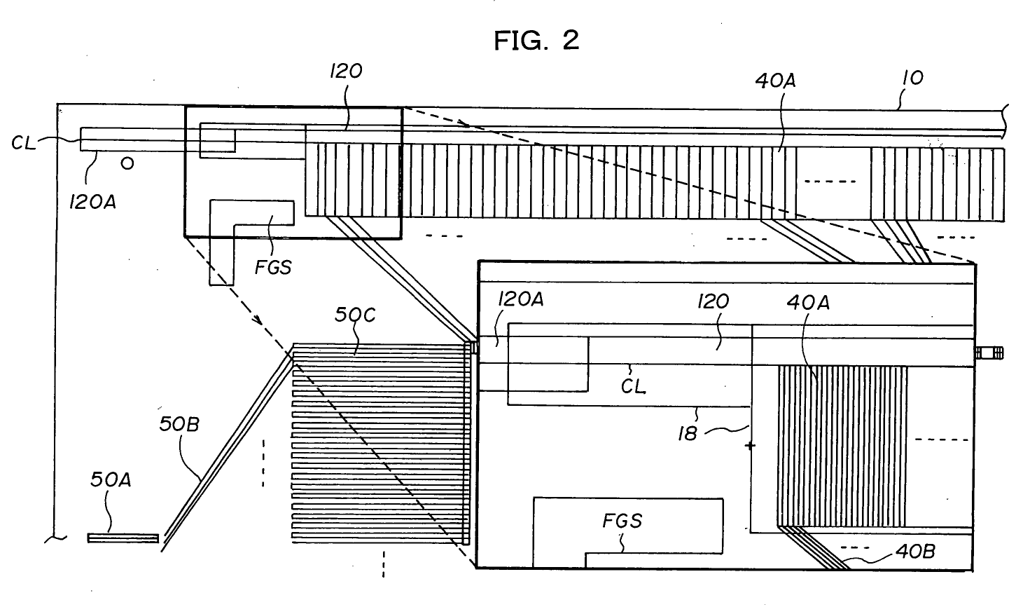

FIG. 2 is an enlarged view of an essential portion of an anodic oxidized feeding terminal shown in FIG. 1, and it is an enlarged view of the left upper portion of FIG. 1. The data line 11 is made of aluminum or aluminum alloy (typically, an alloy Al—Nd comprising aluminum Al and neodymium Nd. The surface of the data line 11 is processed by anodic oxidation, and an interlayer insulator and an electron accelerator are formed on it. To perform the anodic oxidation processing, a feeding terminal 120A on each of the anodic oxidation feeding terminal is immersed in a processing chamber with anodic oxidizing solution placed in it, and a processing voltage is applied from the feeding terminal 120A. The feeding terminal 120A is a terminal of a common bus line 120, and the data line terminal 40A is connected in parallel on it. At the completion of the image display device, the common bus line 120 and the feeding terminal 120A are cut off along a cutting line CL, and the data line terminals 40A are separated independently from each other.

The common bus line 120, together with the data line terminal 40A, is covered with a resist pattern 18 for preventing oxidation except the feeding terminal 120A. At a corner of the cathode substrate 10, a positioning mark FGS is provided, which is used for positioning of a frame glass to seal the cathode substrate with a phosphor substrate superimposed on it. The resist pattern 18 is also provided on a portion of the display region to make up the electron source.

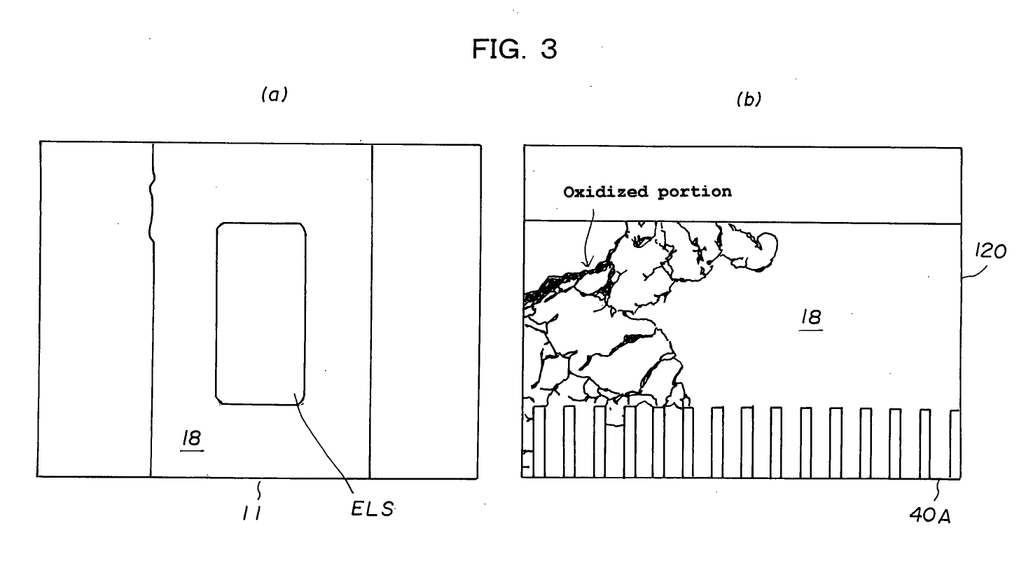

FIG. 3 represents drawings to explain problems when processing voltage is increased from 100 V to 200 V as anodic oxidation processing is performed on the data line and the common bus line connected with the data line. Because the common bus line connected with the data line is cut off and removed later, it is generally not required except the case where it is provided near the feeding terminal 120A for the protection of liquid surface. In this case, however, the resist pattern is provided for the protection of the end of the data line terminal 40A. FIG. 3 (a) shows the condition of the resist pattern 18 to cover the data line 11 on electron source when the processing voltage is increased from 100 V to 200 V to raise withstand voltage yield. The value of the current Ia in this case is 120 mA. As shown in the figure, no peeling occurs on the resist pattern 18, which covers the data line 11 of the electron source, and no damage occurs on an the electron source ELS.

In contrast, on the common bus line 120 and on the data line terminal 40A shown in FIG. 3 (b), peeling occurs on the resist pattern 18 at about 150 V when processing voltage is increased from 100 A and before it reaches 200 V and when the value of the current Ia is about 120 mA. From the peeling portion of the resist pattern to cover the common bus line 120, oxidation and corrosion rapidly occur and these are propagated to the data line terminal 40A, and this causes poor connection.

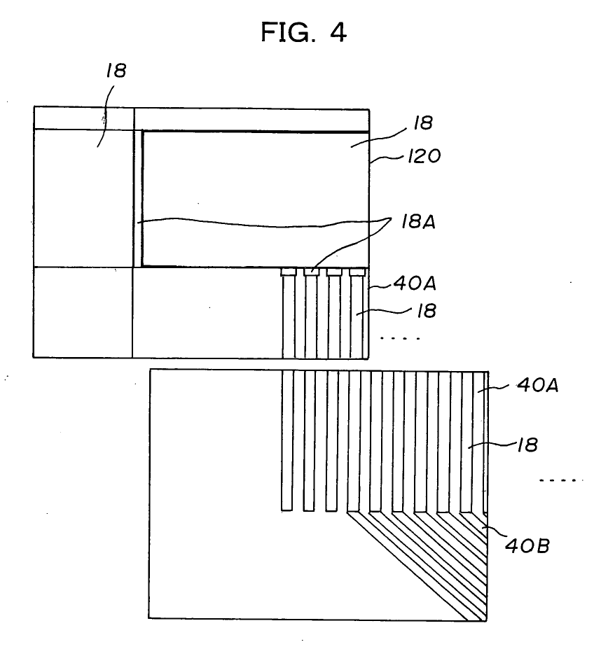

FIG. 4 represents drawings to explain first means for preventing the peeling of the resist pattern when processing voltage is increased. In FIG. 4, it is designed in such manner that the resist pattern 18 is limited to an area on the common bus line 120 made of aluminum (or aluminum alloy) and on the data line terminal 40A so that the resist pattern 18 is not present on a substrate (glass) where adhesive power of the resist is lower. Also, a slit 18A is formed on the resist pattern so that, even when peeling may occur on a resist pattern, the peeling may not be propagated to adjacent resist pattern.

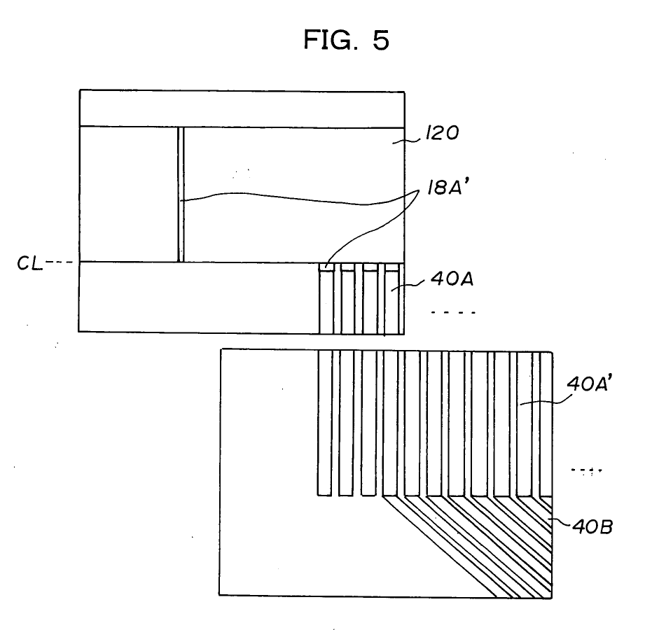

FIG. 5 represents drawings to show the condition of anodic oxidation processing when the cathode substrate with the resist pattern formed on it as shown in FIG. 4 is immersed in an anodic oxidation chamber. Film thickness of the resist pattern is set to 3 μm, and anodic oxidation processing is performed by setting the processing voltage to 200 V and the current to 120 mA respectively. In the figure, reference numerals 18A′ and 40A′ each represents an anodic oxidation layer formed at a position of the slit 18A of the resist pattern. As a result, there was no problem on the electron source, but peeling occurs on the resist pattern due to the common bus line 120, and the peeling of the resist pattern occurs on 10% of the whole area at the highest even on the data line terminal 40A.

### Embodiment 1

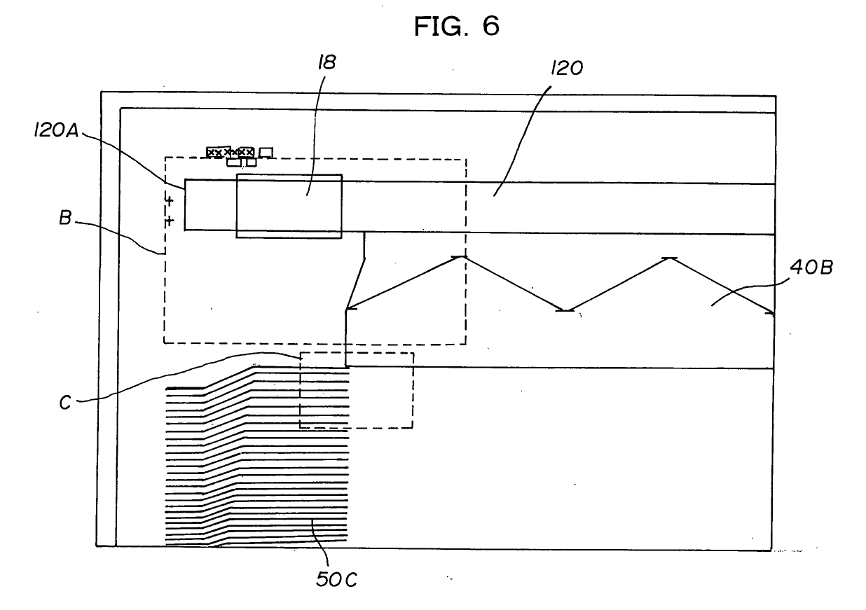

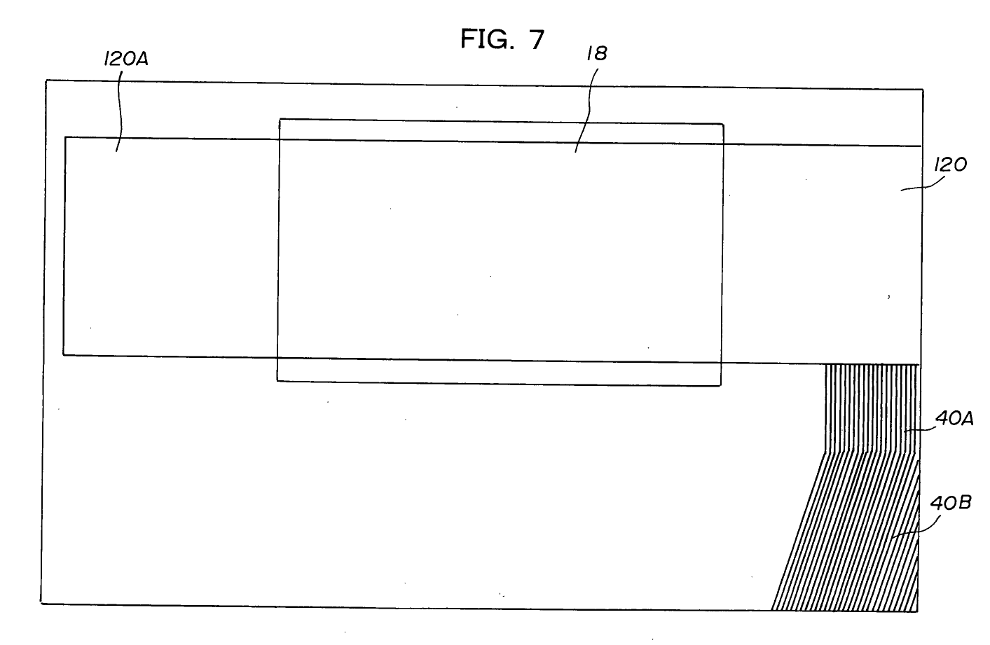

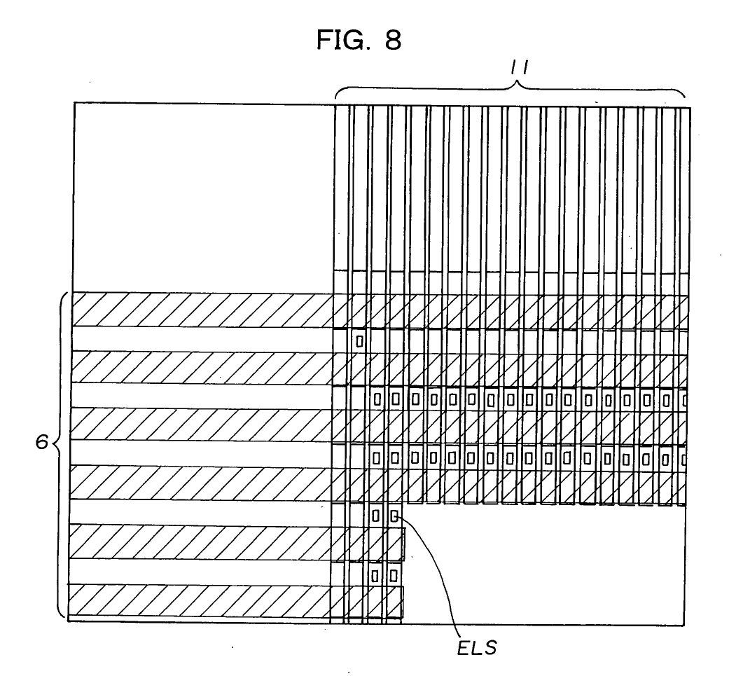

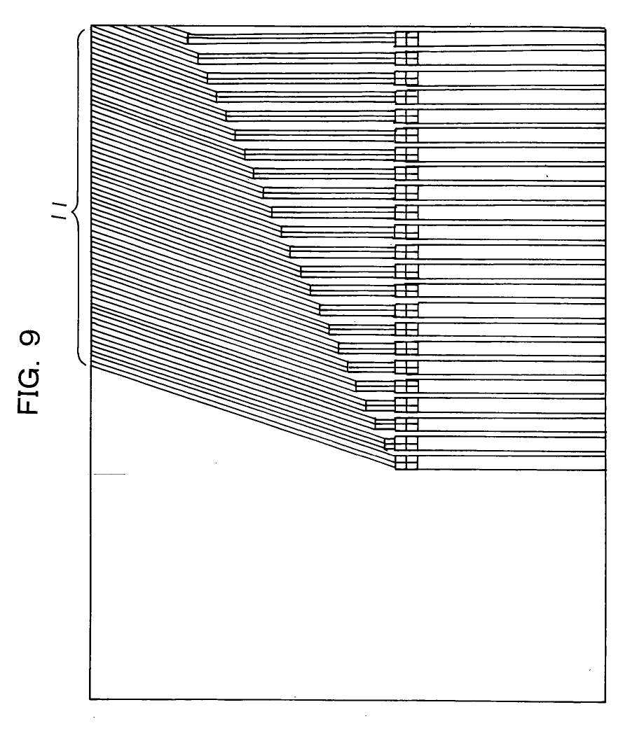

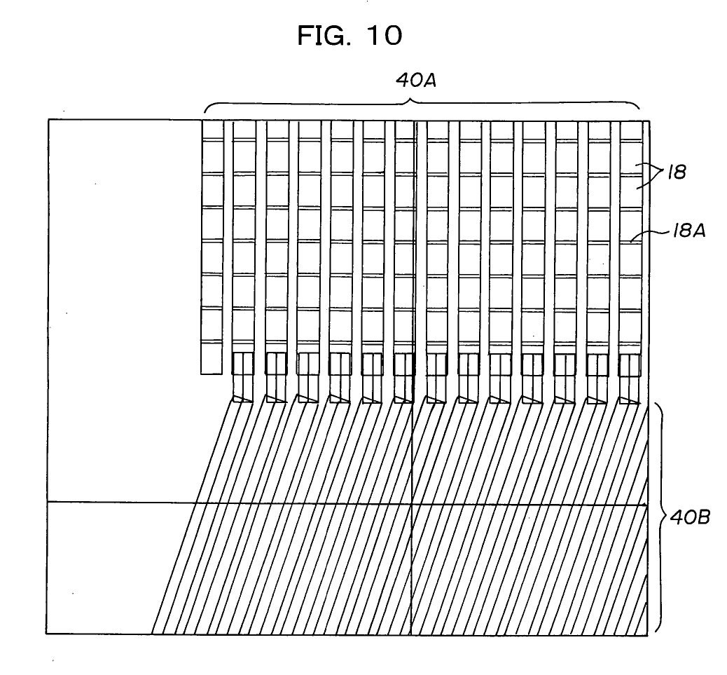

Based on the above description, the present invention will be described on embodiments as given below. FIG. 6 is an enlarged view of a portion A of FIG. 1 to explain Embodiment 1 of the invention. FIG. 7 is an enlarged view of a portion B of FIG. 1. FIG. 8 is an enlarged view of a portion C of FIG. 1. FIG. 9 is an enlarged view of a bus line contracting portion of the data line shown in the upper portion of FIG. 8. FIG. 10 is an enlarged view of a terminal of the data line shown in the upper portion of FIG. 9. In FIG. 6 to FIG. 10, the same symbol as in FIG. 1 to FIG. 5 is used to refer to the same functional component.

In Embodiment 1, the resist patterns to be formed on the terminal 40A of the data line are limited to the bus lines on the terminal 40A as shown in FIG. 10. Specifically, the width of the resist pattern 18 is set to a value approximately equal to the whole width of the bus lines of the terminal 40A so that the resist pattern is not present on the glass substrate between the bus lines. Theoretically, the width of the resist pattern 18 is set to a value equal to the whole region of the width of the bus lines of the terminal 40A. Actually, however, alignment tolerance is required, and it has approximately the same width as the whole region. Thus, the resist pattern is discontinuously formed through division by the slit 18A in extending direction of the bus lines of the terminal 40A. Based on the procedure as given above, the resist pattern 18 is set to the same size as that of the electron source. There is no need to form the resist pattern except that it is provided for the protection of liquid surface near the bus terminal 120A.

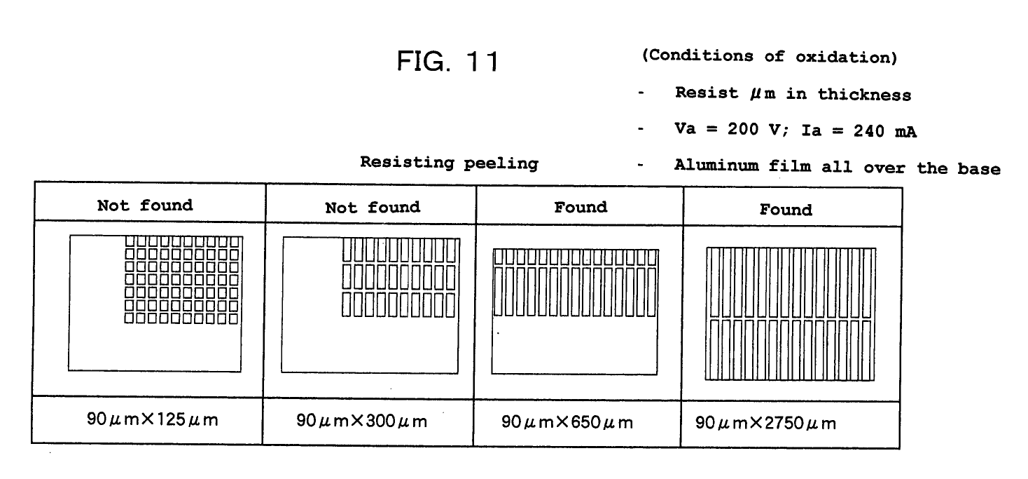

FIG. 11 represents drawings to explain whether the peeling of the resist pattern occurs or not due to the size of the resist pattern formed on the terminal of the data line. Here, the size of the electron source is approximately set to 50 μm×100 μm (width×length). The anodic oxidation processing is performed under the following conditions: film thickness of resist pattern 3 μm; processing voltage Va=200 V; and electric current Ia=240 mA.

Resist peeling does not occur when the size of the resist pattern formed on the terminal of the data line is 90 μm×125 μm (width×length) and 90 μm×300 μm (width×length). In contrast, when it was set to 90 μm×650 μm (width×length) and 90 μm×2750 μm (width×length), resist peeling occurred. These results suggest that the resist peeling is very unlikely to occur when the size of the resist pattern is closer to the size of the electron source, i.e. 50 μm×100 μm (width×length), and that, the longer the length of the resist pattern is, the more frequently the peeling occurs. This may be attributed to the fact that, the smaller the size of the resist pattern is, the smaller the absolute value of residual stress of the film itself of the resist pattern is, and that the peeling of the resist depends on this residual stress.

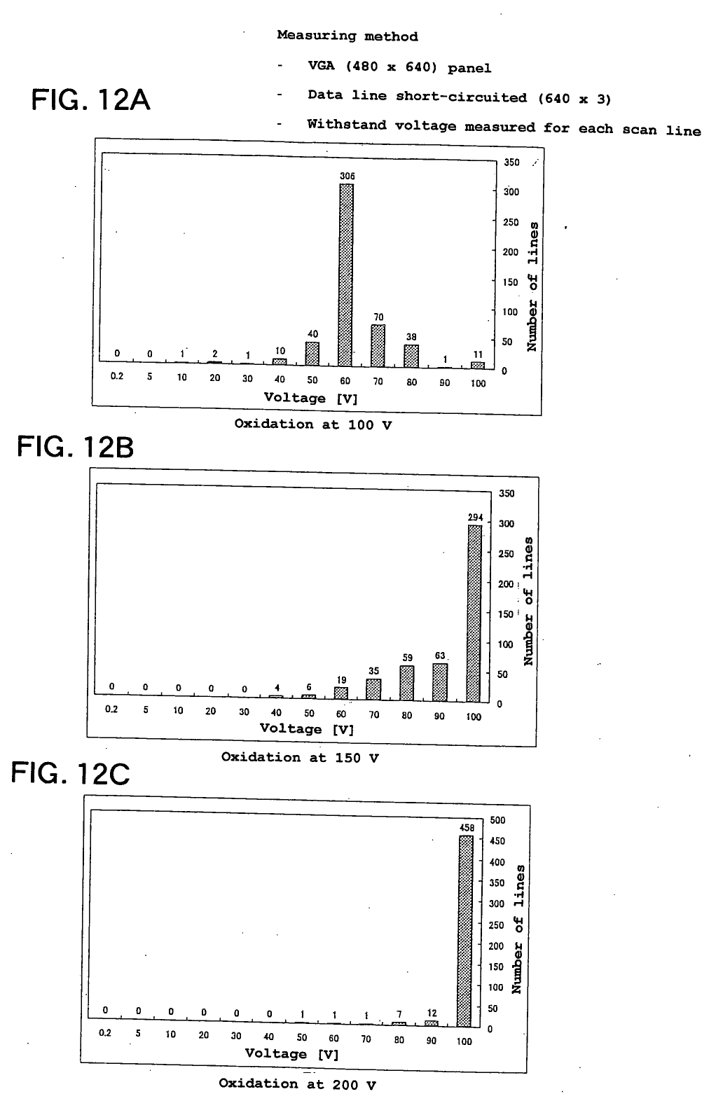

FIG. 12 represents diagrams to explain dielectric breakdown voltage on the interlayer insulator due to the value of oxidation voltage applied on the cathode substrate, which has the data line processed by using the resist pattern as explained in Embodiment 1 of the present invention shown in FIG. 10. Withstand voltage was measured by the number of short-circuits at the intersections of the data lines and the scan lines. Withstand voltage was measured for each scan line by using the cathode substrate of VGA (scan line 480×(data line 640×3)). In the figure, the number of scan lines where short-circuits occurred is shown when voltage was applied between the data line and the scan line. FIG. 12 (a) shows the case where anodic oxidation was performed at the voltage of 100 V, FIG. 12 (b) shows the case where anodic oxidation was performed at 150 V, and FIG. 12 (c) shows the case where anodic oxidation was performed at 200 V. In FIG. 12, anodic oxidation is simply given as “oxidation”, and the number of data lines is simply given as “number of lines”.

FIG. 12 (a) shows the case where the data lines were processed by anodic oxidation at 100 V to turn to the interlayer insulator. As soon as the voltage applied between the data line and the scan line reached 10 V, short-circuiting occurred. When the voltage of 60 V was applied, the number of the short-circuited scan lines exceeded 300. FIG. 12 (b) shows the case where the data lines were processed by anodic oxidation at 150 V to turn to the interlayer insulator, and short-circuiting occurred when the voltage applied between the data line and the scan line reached 40 V. When the voltage applied was 100 V, the number of short-circuited scan lines was nearly 300. FIG. 12 (c) shows the case where the data lines were processed by anodic oxidation at 200 V to turn to the interlayer insulator. In this case, short-circuiting occurred when the voltage applied between the data line and the scan line was 50 V. When the voltage applied was 100 V, the number of the short-circuited scan lines exceeded 450. These results reveal that, when the resist pattern of Embodiment 1 of the present invention is used, higher voltage may be applied for anodic oxidation processing of the data line and that the interlayer insulator with high withstand voltage can be produced with high throughput.

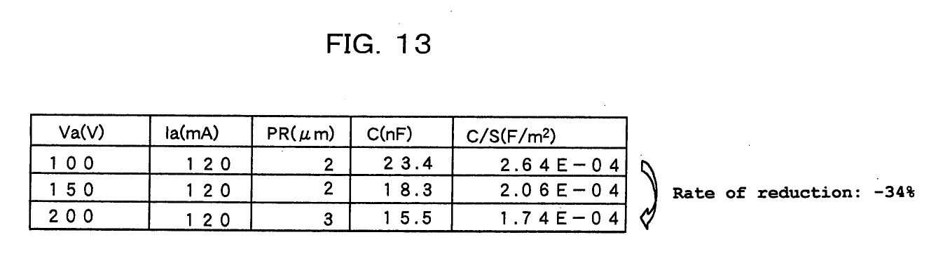

FIG. 13 is a table to explain capacity reducing effects of the pixel provided with data lines processed by using the resist pattern as explained in Embodiment 1 of the present invention shown in FIG. 10. In FIG. 13, film thickness of anodic oxidized layer PR (μm), capacittance C (nF) at the intersection with the scan line, and capacittance per unit area C/S (F/m²) are shown when electric current was set to 120 mA with respect to the applied voltage of 100 V, 150 V and 200 V respectively. In this case, the scan line is designed in 3-layer structure of Cr/Al/Cr, and a layer of SiON is formed on the anodic oxidized layer. FIG. 13 indicates that the capacity of pixel is reduced by 34% when the voltage for anodic oxidation is set to 100 V to 200 V by using the resist pattern as explained in Embodiment 1. As a result, the load of the driving circuit can be reduced.

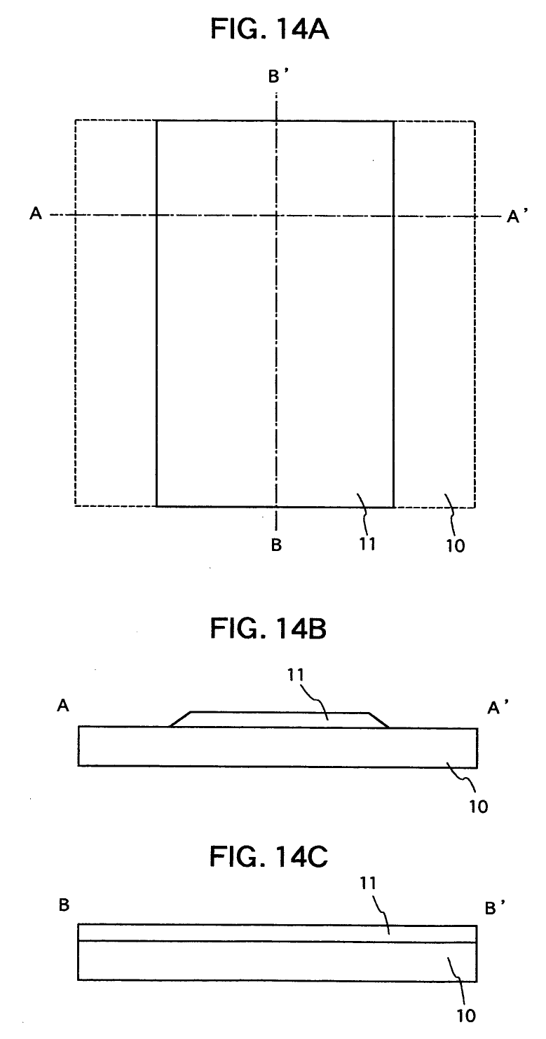

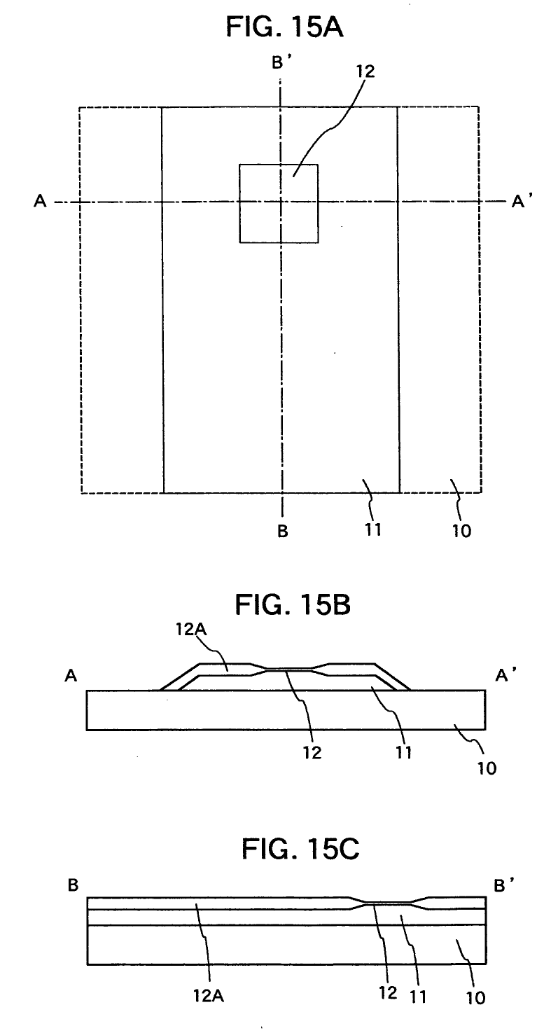

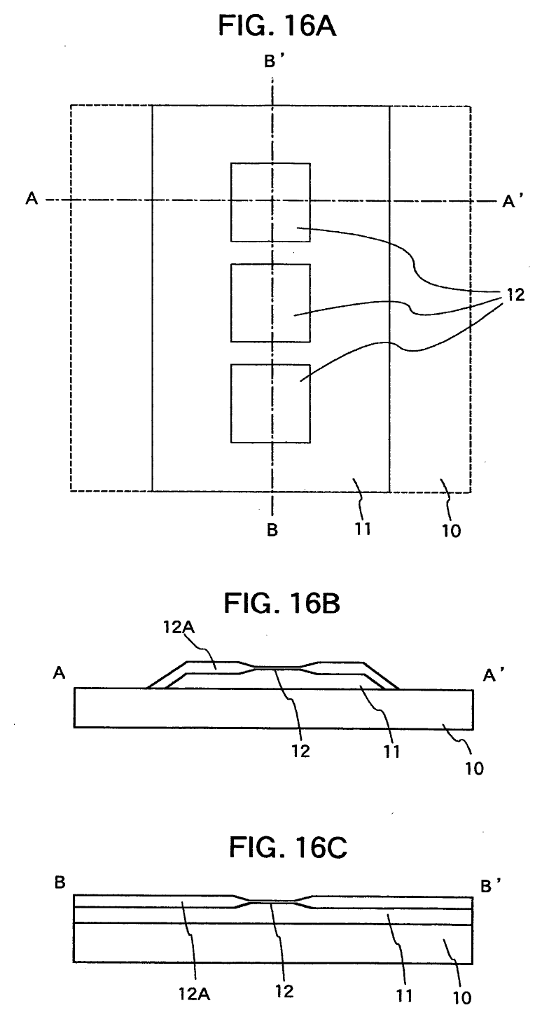

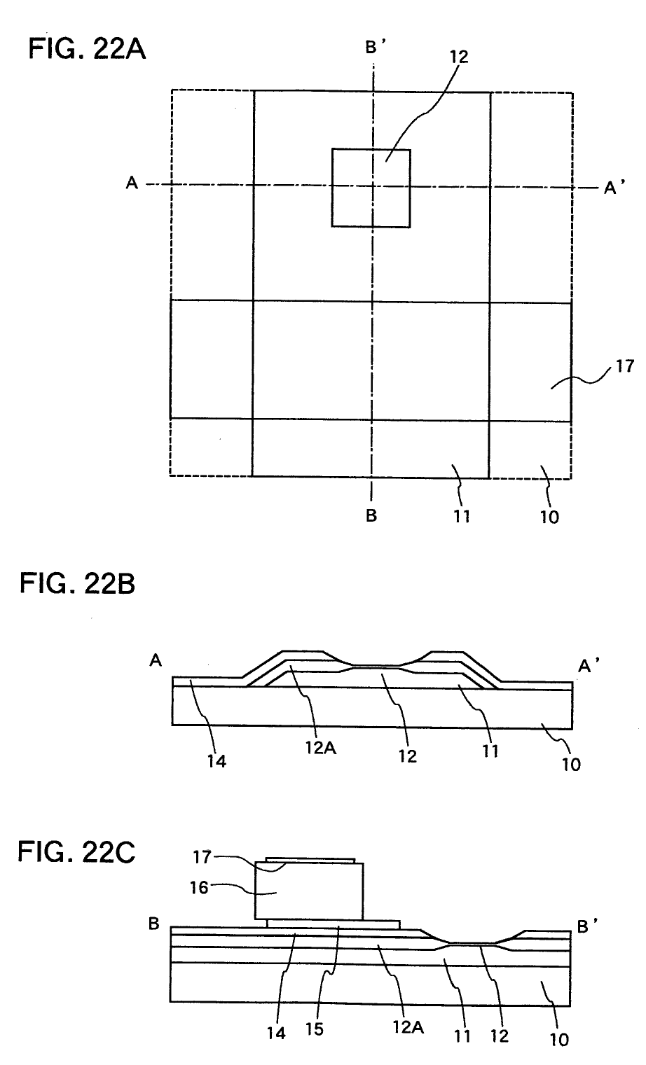

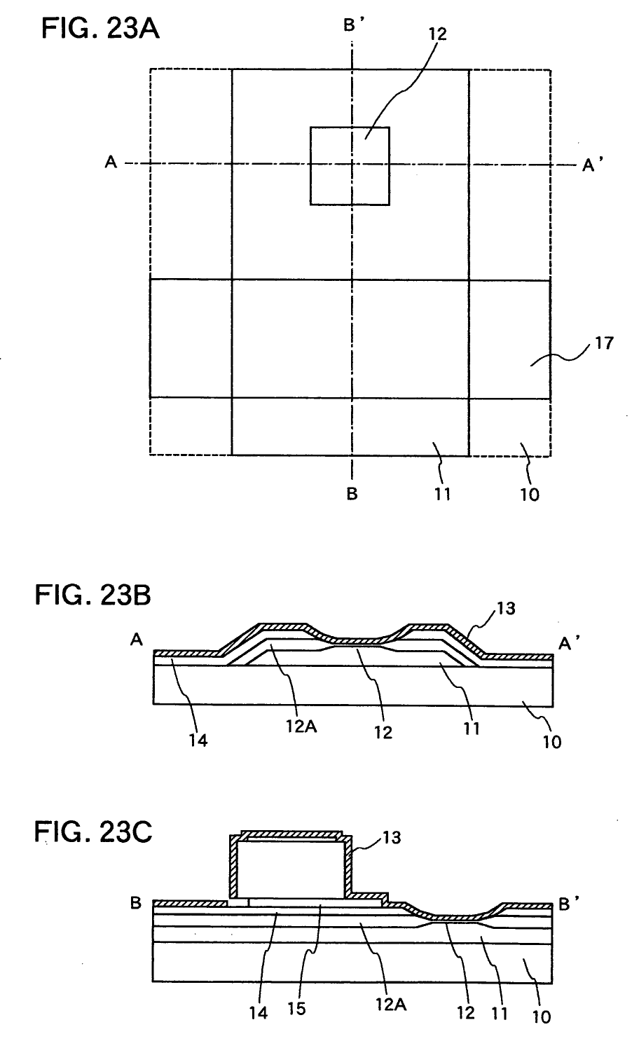

Next, description will be given on the processing for forming the cathode substrate of the image display device of the present invention referring to FIG. 14 to FIG. 23. FIG. 15 represents process drawings similar to those of FIG. 14. FIG. 16 represents process drawings similar to those of FIG. 15, and so on, and FIG. 23 represents process drawings similar to those of FIG. 22.

In FIG. 14, a metal film for a signal electrode 11 (hereinafter referred as “bottom electrode”) is formed on the cathode substrate 10 made of an insulating material such as glass. As the material of the bottom electrode 11, aluminum (Al) or aluminum alloy is used. Here, Al—Nd alloy, i.e. aluminum doped with neodymium (Nd) by 2 atom %, is used. For the formation of this metal film, sputtering method is adopted, for instance. Film thickness is set to 300 nm. After the deposition of the film, a stripe-like bottom electrode as shown in FIG. 14 is formed by photolithography process and etching process. As the etching solution, wet etching using a mixed aqueous solution of phosphoric acid, acetic acid, and nitric acid is applied.

In FIG. 15, the resist pattern is put on a part of the bottom electrode 11, and the surface is locally processed by anodic oxidation. Next, the resist pattern used for local oxidation is peeled off. The surface of the bottom electrode 11 is processed again by anodic oxidation, and an insulator layer (tunneling insulator) 12 is formed on the bottom electrode 11. Around the tunneling insulator 12, a field insulator 12A is formed. In this case, oxidation is not performed on the region where oxide film has grown, and the oxide film grows only in the region, which has been covered with the resist in the preceding process.

FIG. 16 represents the drawings similar to those of FIG. 15 on the terminal of the data line. According to the present invention, a plurality of insulators 12 similar to pixel portions are also formed on the terminal of the data line.

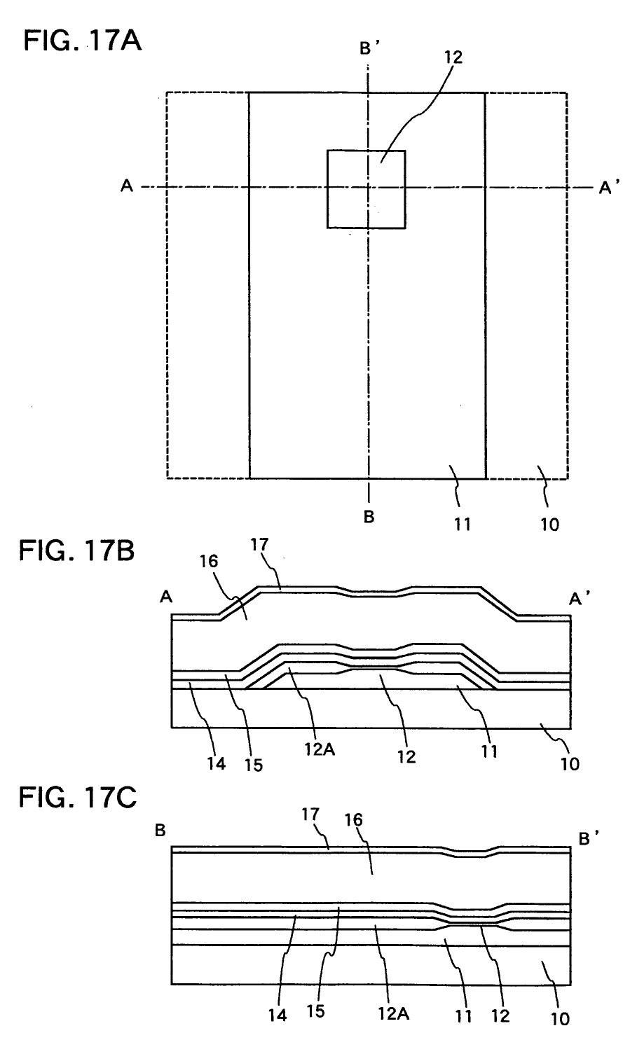

In FIG. 17, silicon nitride SiN (e.g. Si₃N₄) is formed as an insulator 14 by sputtering method. A layer of chromium (Cr) is formed in thickness of 100 nm as a contact electrode 15. Then, aluminum alloy is formed in thickness of 2 μm as a top electrode bus line (top electrode bus line; scan line bus line) 16, and a layer of chromium (Cr) is formed on it as a cap electrode 17.

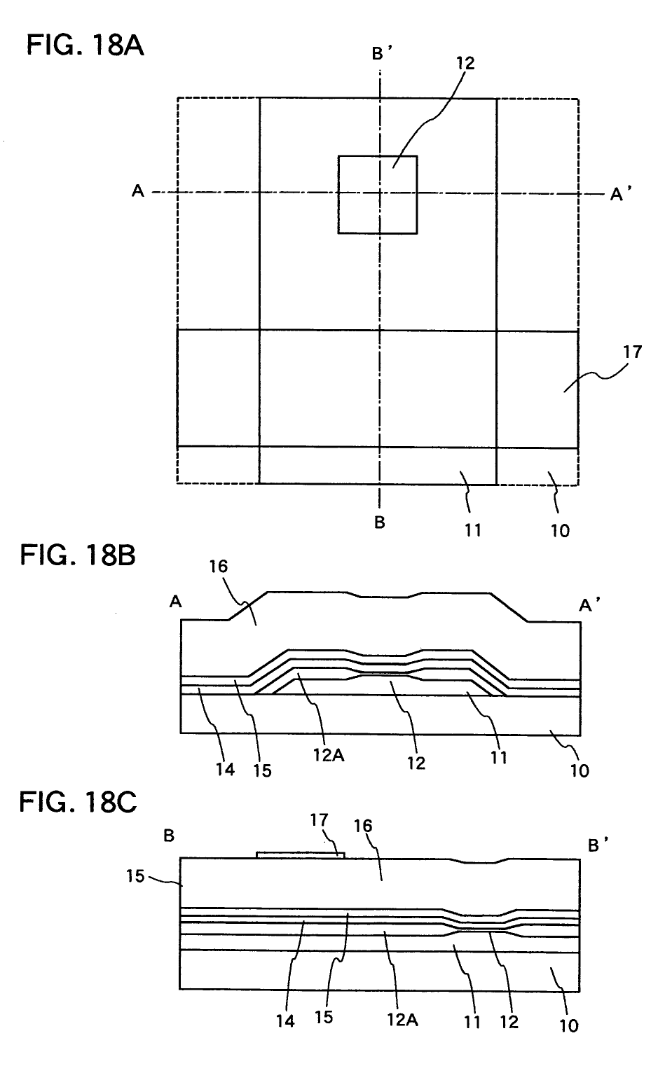

In FIG. 18, Cr of the cap electrode 17 is left on a portion, which serves as the scan line. For the etching of Cr, a mixed aqueous solution of cerium diammonium nitrate and nitric acid is suitable. In this case, it is necessary to design in such manner that line width of the cap electrode 17 is narrower than line width of the top electrode bus line 16 to be produced in the next process. This is because the top electrode bus line 16 is made of aluminum alloy of 2 μm in thickness and side etching of the same extent is inevitably occurs due to the wet etching. If proper consideration is not given on this point, the cap electrode 17 may protrude above the eave from the top electrode bus line 16. The protruded portion of the cap electrode 17 above the eave is poor in strength. It is very likely to collapse during the manufacturing process or it may be peeled off. This causes short-circuiting between the scan lines, and this may lead to electrostatic focusing when high voltage is applied and may induce serious arc discharge.

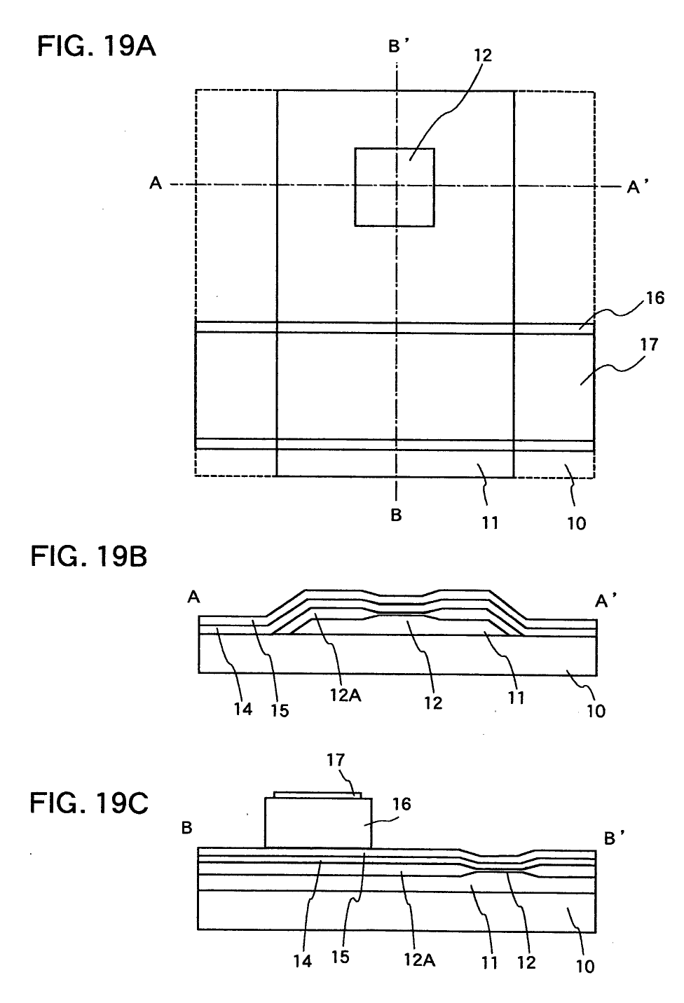

In FIG. 19, the top electrode bus line 16 is processed to have a stripe-like form in a direction perpendicularly crossing the bottom electrode 11. As the etching solution, a mixed aqueous solution (PAN) of phosphoric acid, acetic acid and nitric acid is suitable, for instance.

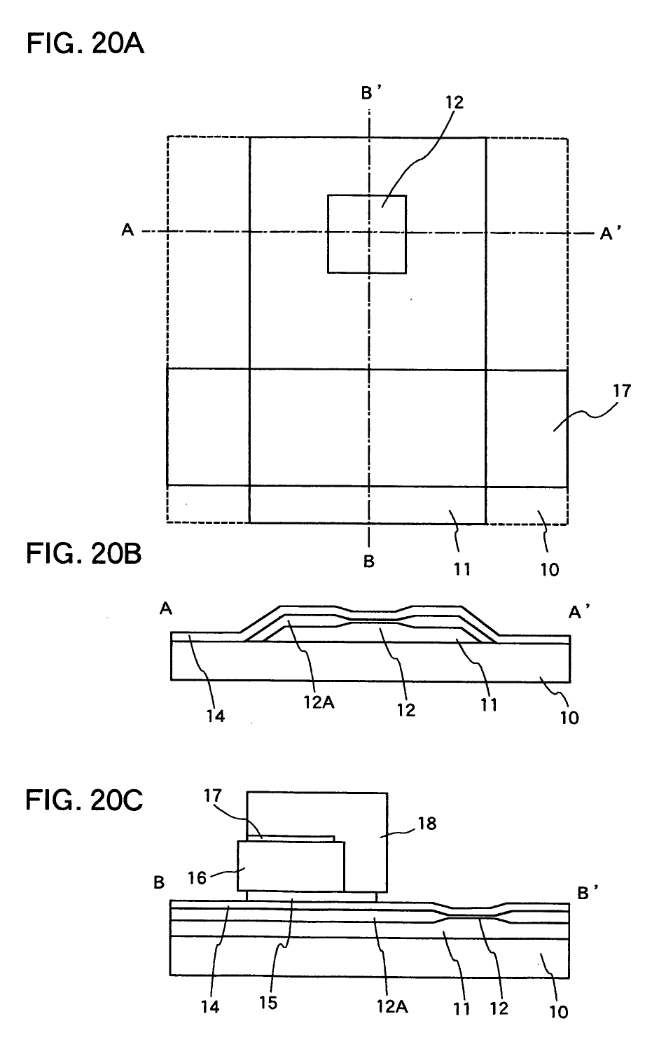

In FIG. 20, the contact electrode 15 is processed in such manner that it is protruded toward the opening side of the insulator film 15 or that it is retracted with respect to the top electrode bus line 16 (to form an undercut). For this purpose, wet etching should be performed by placing the photoresist pattern 18 on the contact electrode 15 in the former case and on the cap electrode 17 in the latter case. As the etching solution, a mixed solution of cerium diammonium nitrate and nitric acid is suitable. In this case, the insulator under-layer 14 plays a role of an etching stopper to protect the tunneling insulator 12 from the etching solution.

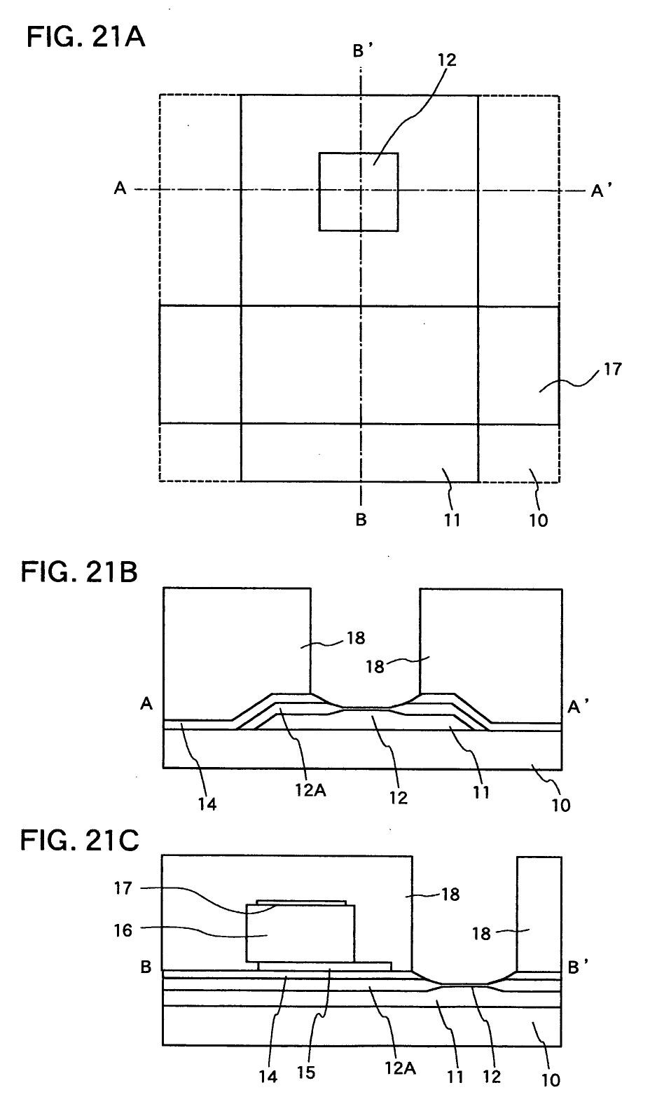

In FIG. 21, the resist pattern 18 is provided and an opening is formed on a part of the insulator 14 by photolithography and dry etching in order to open an electron emission region. As the etching gas, a mixed gas of CF₄ and O₂ is suited. Anodic oxidation is performed again on the exposed tunneling insulator 12, and the damage caused by etching may be repaired. The resist pattern is removed as shown in FIG. 22.

As shown in FIG. 23, the top electrode 13 is formed and the cathode substrate (electron source substrate, cathode substrate) is completed. For film deposition on the top electrode 13, a shadow mask is used, and sputtering method is performed so that the film may not be deposited on the terminal of electric wiring arranged around the substrate. Poor covering occurs on the undercut structure as described above of the top electrode bus line 16, and the top electrode 13 is automatically separated for each scan line. As the material of the top electrode 13, a laminated film of Ir, Pt and Au is used, the thickness of each film being several nm. As a result, contamination or damage caused by photolithography and etching to the top electrode 13 or to the tunneling insulator 12 can be avoided.

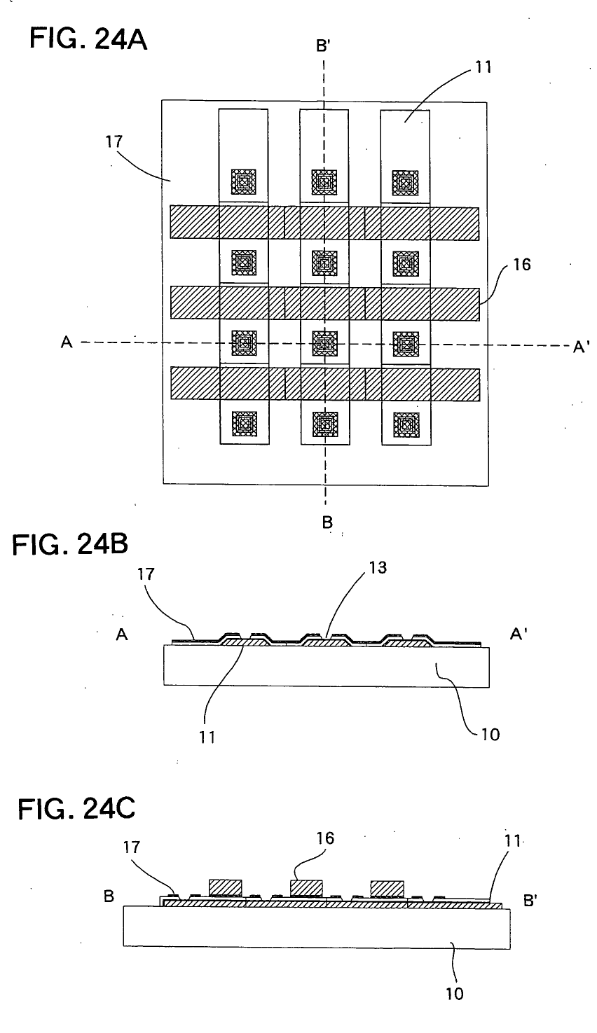

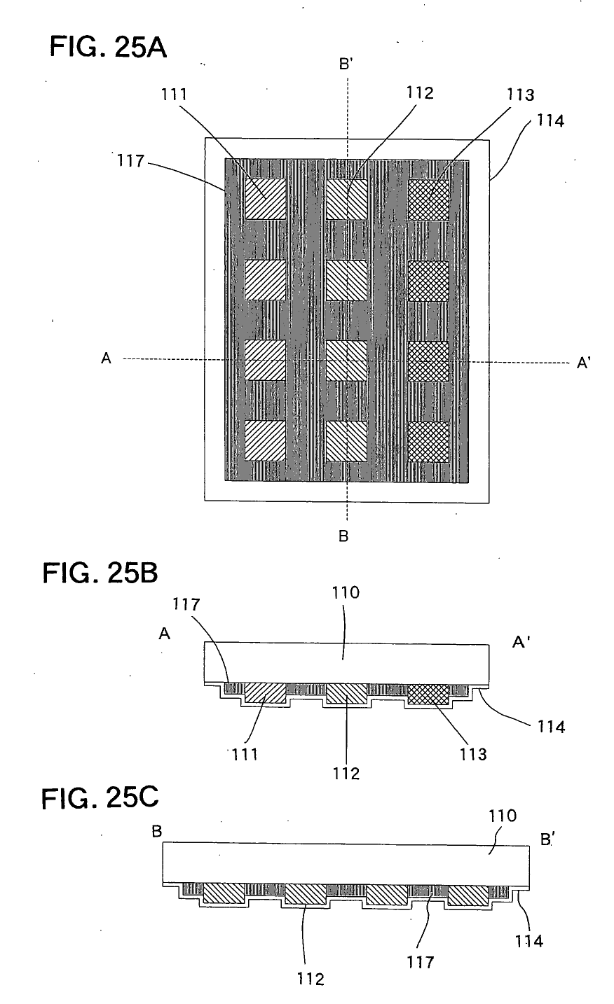

Now, description will be given on an example of arrangement of the image display device using MIM type cathode substrate referring to FIG. 24 and FIG. 25. First, a cathode substrate is prepared, in which a plurality of MIM type electron sources are arranged on the cathode substrate 10 by the process as described above. To facilitate explanation, a plan view and cross-sectional views of a (3×4)-dot MIM type electron source substrate are shown in FIG. 24. Actually, a matrix of MIM type electron sources corresponding to the number of display dots is formed.

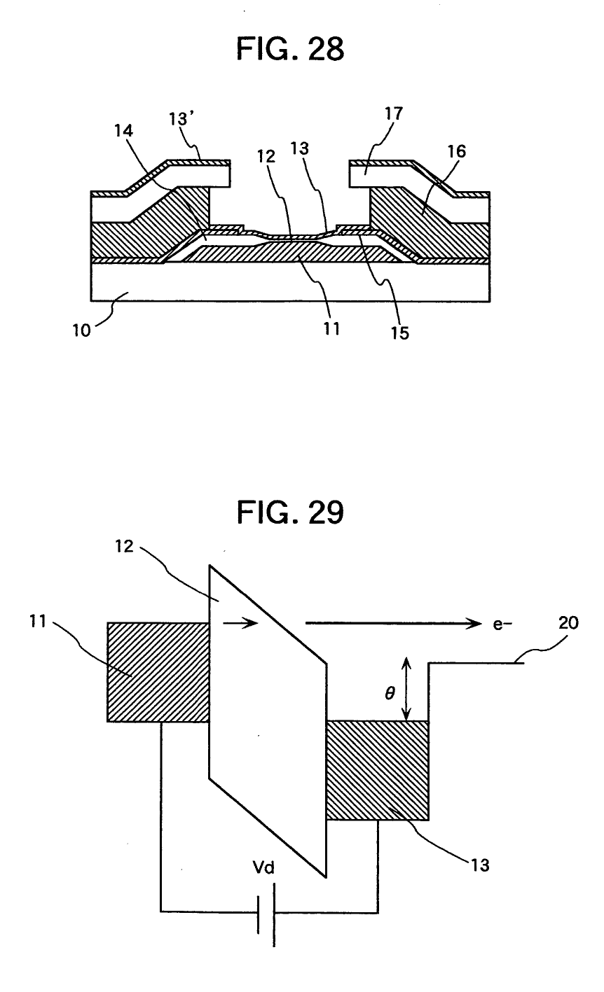

FIG. 24 (a) is a plan view, FIG. 24 (b) is a cross-sectional view along the line A-A′ of FIG. 24 (A), and FIG. 24 (c) is a cross-sectional view along the line B-B′ of FIG. 28 (a). The same functional component as in the above description is referred by the same symbol.

Now, description will be given on an arrangement of an anode substrate in the manufacturing method by referring to FIG. 25. As an anode substrate 110, a light-transmitting glass is used, for instance. First, a black matrix 117 is formed for the purpose of promoting the contrast of the image display device. To form the black matrix 117, a mixed solution of PVA (polyvinyl alcohol) and ammonium dichromate is coated on the anode substrate 110. A portion where the black matrix 117 is to be formed is exposed to ultra-violet ray, and unexposed portion is removed. Then, a solution with graphite powder dissolved in it is coated on that portion, and PVA is lifted off.

Next, a red phosphor layer 111 is formed. A mixed aqueous solution of PVA (polyvinyl alcohol) and ammonium dichromate with phosphor particles is coated on the anode substrate 110. Then, the portion where phosphor layer is formed is exposed to ultra-violet ray, and unexposed portion is removed under running water. The red phosphor layer 111 is formed. Then, a green phosphor layer 112 and a blue phosphor layer 113 are formed in similar manner. As the phosphor layer, Y₂O₂S:Eu may be used for the red phosphor layer (P22-R), ZnS:Cu, Al may be used for the green phosphor layer (P22-G), ad ZnS:Ag may be used for the blue phosphor layer (P22-B).

Next, the surface is flattened by filming using a film such as nitrocellulose. Aluminum is deposited by vacuum deposition to have film thickness of about 75 nm all over the anode substrate 110, and it is turned to a metal back 114. This metal back 114 serves as an accelerator electrode. Then, the anode substrate 110 is heated to about 400° C. in the atmospheric air, and filming and organic substances such as PVA are decomposed by heating. Now, the anode substrate is completed. The anode substrate 110 thus manufactured and the cathode substrate 10 are sealed with a frit glass 115 via a spacer 30 with a frame glass 116 positioned around the display region.

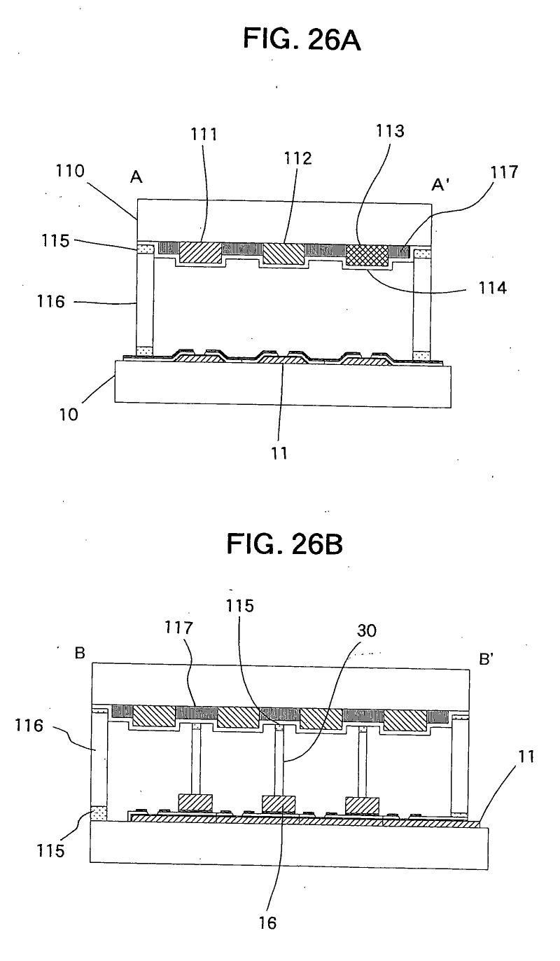

FIG. 26 represents cross-sectional views of the image display device where the cathode substrate and the anode substrate are affixed together. FIG. 26 (a) represents a cross-section along the line A-A′ of FIG. 25, and FIG. 26 (b) represents a cross-section along the line B-B′ of FIG. 25. The height of the spacer 30 is set to such a value that a distance between the anode substrate 110 and the cathode substrate 10 affixed together is to be about 1 to 3 mm. As the spacer 30, a planar glass or ceramics is placed on the top electrode bus line 16. In this case, the spacer 30 does not block light emission because the spacer is placed under the black matrix 117 closer to the display substrate. To facilitate the explanation, the spacer 30 is provided for each dot for emission of colors of R (red), G (green), and B (blue), i.e. on the top electrode bus line 16. Actually, however, the number (density) of the spacers 30 may be decreased to such an extent that it is allowable in providing sufficient mechanical strength. For example, the spacers may be placed for every several centimeters.

Although it has not been explained here, even when a pillar type spacer or a cross type spacer is used, panel assembling can be carried out by similar procedure. For the sealed panel, the air is pumped out to reach vacuum condition of about 10⁻⁷ Torr for attaining perfect sealing. After the sealing, the incorporated getter is activated, and the space within the container comprising the substrate and the frame is maintained under high vacuum conditions. For instance, in case a getter with Ba as main component is used, a getter film can be formed by high frequency induction heating. Also, a non-evaporation type getter using Zr as main component may be used. Thus, the display panel using MIM type electron sources can be completed. Because a distance between the anode substrate 110 and the cathode substrate 10 is as long as about 1 to 3 mm, the voltage to be applied on the metal back 114 can be set to high voltage, i.e. to 1 to 10 kV. As a result, a phosphor for cathode ray tube (CRT) can be used as the phosphor.

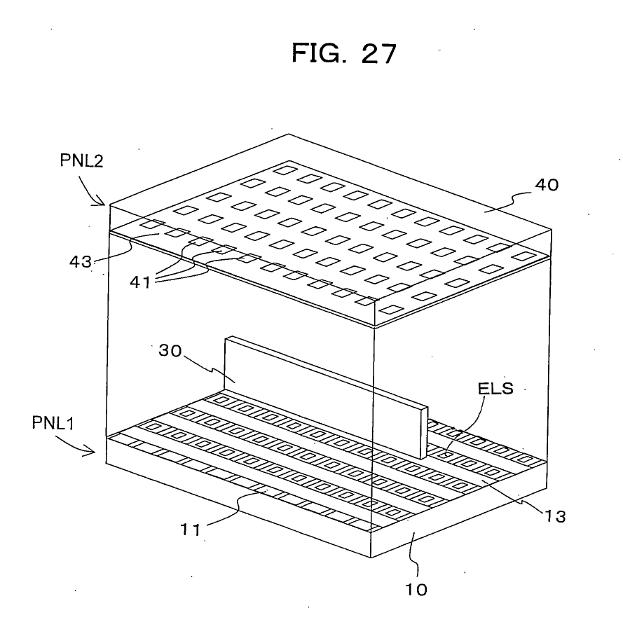

FIG. 27 is an explosive perspective view to explain general features of an overall arrangement of the image display device according to the present invention. A backside panel PNL1 to make up the cathode substrate comprises a top electrode 13 extended in one direction on inner surface of the cathode 10 and aligned in other direction perpendicularly crossing said one direction and having a plurality of scan lines where scanning signals are sequentially applied in said other direction, a plurality of data lines 11 (bottom electrodes 11) aligned in said one direction as if the data lines extended in said other direction and crossing the top electrode 13 having scan lines, and electron sources ELS provided near each intersection of the top electrode 13 and the bottom electrode 11. The bottom electrode 11 is provided on the cathode substrate 10, and the top electrode 13 is formed on it via the interlayer insulator.

A front side panel PNL2 to make up the anode substrate comprises three sub-pixels 41 representing three colors (red (R), green (G) and blue (B)) respectively divided from each other by a black matrix 43 on inner surface of the substrate 40. In this arrangement, the spacers 30 are placed on the scan lines 13. The panels are affixed together via a frame glass (not shown) with predetermined spacing and these are sealed under vacuum condition. Only one of the spacers 30 is shown in the figure, while the spacers are normally distributed for the top electrodes 13 by dividing to a plurality of spacers—each to match each of the top electrodes 13 to make up one scan line.

What is claimed is:

1. An image display device provided with a vacuum panel container, comprising a cathode substrate where a plurality of thin-film type electron sources are arranged with predetermined spacing, an anode substrate where spot-like or linear phosphor films are arranged to face to each other, a plurality of spacers for supporting said cathode substrate and said anode substrate with predetermined spacing, and a frame glass for maintaining vacuum condition, wherein there are provided a plurality of electric bus lines extending in row direction and in column direction crossing perpendicularly via interlayer insulators, and said thin-film type electron sources are connected with said electric bus lines in column direction and in row direction at positions corresponding to each of intersection coordinates;
each of said cold cathode type electron sources comprises a bottom electrode made of aluminum or aluminum alloy, a top electrode, and an electron accelerator interposed between said bottom electrode and said top electrode; and
a terminal of said bottom electrode is formed around said cathode substrate as being extended, and there are a plurality of discontinuous non-oxidized regions or regions including electron accelerator in extending direction almost over the entire region in width direction of the said terminal.

2. An image display device according to claim 1, wherein said electron accelerator is an anodic oxidized film of said bottom electrode.

3. An image display device according to claim 1, wherein said interlayer insulator is an anodic oxidized film of said bottom electrode.

4. A method for manufacturing an image display device provided with a vacuum panel container, comprising a cathode substrate where a plurality of thin-film type electron sources are arranged with predetermined spacing, an anode substrate where spot-like or linear phosphor films are arranged to face to each other, a plurality of spacers for supporting said cathode substrate and said anode substrate with predetermined spacing, and a frame glass for maintaining vacuum condition, wherein there are provided a plurality of electric bus lines extending in row direction and in column direction crossing perpendicularly via interlayer insulators, and said thin-film type electron sources are connected with said electric bus lines in column direction and in row direction at positions corresponding to each of intersection coordinates;
each of said cold cathode type electron sources comprises a bottom electrode made of aluminum or aluminum alloy, a top electrode, and an electron accelerator interposed between said bottom electrode and said top electrode, wherein said method comprises the steps of:
forming a terminal of said bottom electrode by extending said bottom electrode to around said cathode electrode;
forming a resist for preventing oxidation by dividing to a plurality of resists in form of said terminal to cover said terminal of said bottom electrode; and
forming a plurality of non-oxidized regions through processing of anodic oxidation on said terminal.

5. A method for manufacturing an image display device according to claim 4, wherein said resist for the prevention of oxidation is formed only on said bottom electrode.
